(19) United States
(12) Patent Application Publication
(10) Pub. No.: US 2025/0070491 A1
(43) Pub. Date: Feb. 27, 2025

(54) SOCKET CONTACT PIN DEPOPULATION AND HOUSING CUT-OUT IN LOW S-G REGION FOR POST-RESONANCE CROSSTALK SUPPRESSION IN HIGH FREQUENCY APPLICATIONS

(71) Applicant: Intel Corporation, Santa Clara, CA (US)

(72) Inventors: Saikat MONDAL, Chandler, AZ (US); Zhichao ZHANG, Chandler, AZ (US); Oluwafemi AKINWALE, Hayward, CA (US); Kemal AYGÜN, Tempe, AZ (US)

(21) Appl. No.: 18/238,381

(22) Filed: Aug. 25, 2023

(51) Int. Cl. H01R 12/71; H01L 23/00; H01R 13/24; H01R 13/405

(52) U.S. Cl. CPC H01R 12/714; H01L 24/16; H01R 13/2442; H01R 13/405; H01L 2224/16225

(57) ABSTRACT

Embodiments disclosed herein include sockets and socket modules. In an embodiment, a socket module comprises a housing and a first pin through the housing in a first row of pins. In an embodiment, a second pin is through the housing in a second row of pins. In an embodiment, at least three intervening rows of pins are between the first row of pins and the second row of pins. In an embodiment, one or more pin locations in the at least three intervening rows of pins are depopulated.

### BACKGROUND

Crosstalk is a key high speed signaling performance metric to enable the scaling of the differential channel speed for high data rate applications. Conventionally, more ground contact pin isolation is used between the transmit (Tx) and receive (Rx) pairs to reduce the crosstalk. For instance, three or more rows of ground pins are typically provided between Tx pairs and Rx pairs in order to minimize crosstalk. However, this technique only works well until the resonance frequency of the contact pin is reached. Beyond the resonance frequency, the crosstalk level does not get reduced with more ground pin isolation, especially for near-end crosstalk (NEXT).

Hence, the boundary condition of the socket contact (e.g., contact height, contact architecture, etc.) would need to be changed in order to enable higher data rates. The contact height can only be scaled down to a certain extent. Changes to the contact architecture are costly. Entire pin assembly redesign is necessary, and compatibility between different generations is lost.

### BRIEF DESCRIPTION OF THE DRAWINGS

FIG. 1A is a cross-sectional illustration of a socket module with an array of sockets through a socket housing, in accordance with an embodiment.

FIG. 1B is a cross-sectional illustration of an electronic package with a socket module that couples a board to a package substrate, in accordance with an embodiment.

FIG. 2A is a plan view illustration of a portion of a socket module that includes Tx pins and Rx pins separated from each other by four rows of ground pins, in accordance with an embodiment.

FIG. 2B is a cross-sectional illustration of the socket module in FIG. 2A, in accordance with an embodiment.

FIG. 3A is a plan view illustration of a portion of a socket module that includes Tx pins and Rx pins that are separated from each other by rows of ground pins, where one or more of the ground pins are depopulated, in accordance with an embodiment.

FIG. 3B is a cross-sectional illustration of the socket module in FIG. 3A, in accordance with an embodiment.

FIG. 4A is a plan view illustration of a portion of a socket module that includes Tx pins and Rx pins that are separated from each other by rows of ground pins, where two rows of the ground pins include depopulated pins, in accordance with an embodiment.

FIG. 4B is a cross-sectional illustration of the socket module in FIG. 4A, in accordance with an embodiment.

FIG. 5A is a plan view illustration of a portion of a socket module that includes Tx pins and Rx pins that are separated from each other by ground pins and a cutout through the socket housing, in accordance with an embodiment.

FIG. 5B is a cross-sectional illustration of the socket module in FIG. 5A, in accordance with an embodiment.

FIG. 6A is a graph showing near end crosstalk improvement for the various embodiments described herein.

FIG. 6B is a graph showing COM comparisons between a baseline and an embodiment with depopulated pins between the Tx pins and the Rx pins, in accordance with an embodiment.

FIG. 7 is a cross-sectional illustration of an electronic system that includes a socket module with depopulated ground pins between a Tx pin and an Rx pin, in accordance with an embodiment.

FIG. 8 is a schematic of a computing device built in accordance with an embodiment.

### EMBODIMENTS OF THE PRESENT DISCLOSURE

Described herein are electronic systems, and more particularly, socket depopulation and housing cutouts in socket based second level interconnect architectures, in accordance with various embodiments. In the following description, various aspects of the illustrative implementations will be described using terms commonly employed by those skilled in the art to convey the substance of their work to others skilled in the art. However, it will be apparent to those skilled in the art that the present disclosure may be practiced with only some of the described aspects. For purposes of explanation, specific numbers, materials and configurations are set forth in order to provide a thorough understanding of the illustrative implementations. However, it will be apparent to one skilled in the art that the present disclosure may be practiced without the specific details. In other instances, well-known features are omitted or simplified in order not to obscure the illustrative implementations.

Various operations will be described as multiple discrete operations, in turn, in a manner that is most helpful in understanding the present disclosure, however, the order of description should not be construed to imply that these operations are necessarily order dependent. In particular, these operations need not be performed in the order of presentation.

As noted above, interconnect architectures are rapidly approaching their speed limits. One bottleneck is the socket module provided between the board and the package substrate. The limit is largely due to problems with near end crosstalk (NEXT). NEXT can be mitigated by providing more rows of grounding pins between the transmit (Tx) pins and the receive (Rx) pins. For example, existing architectures may use four or more rows of ground pins between Rx pins and Tx pins.

However, the increased grounding has a limited effect, especially at higher frequencies. More particularly, as the resonant frequency of the pins is reached, increased grounding becomes less effective. At the resonant frequency, energy from the Tx pins can easily propagate between rows of ground pins to the Rx pins, and vice-versa. In existing architectures, the resonant frequency is typically around 30 GHz. As such, higher frequencies that enable greater data rates are unachievable.

Some approaches to combat this limit have been proposed. One approach is to reduce the height of the pins. This increases the resonant frequency, and can buy some additional signaling speed. However, the height of the pins can only be scaled to a certain degree, and high data rates are not able to be achieved. Another option is to use a redesigned pin architecture. A redesign may allow for higher data rates, but at a significant engineering cost.

Accordingly, embodiments disclosed herein include socket modules that include improved NEXT protection. This can allow for an increase in data rates. For example, existing land grid array (LGA) pin architectures that were originally designed for up to 64 Gbps can be extended up to 112 Gbps or higher. Further, the modifications described herein use the same layout and pattern of existing LGA architectures. As such, minimal redesign is needed in order to achieve the higher data rates for next generation products.

In an embodiment, the socket modules disclosed herein include three or more rows of ground pins between the Tx pairs and the Rx pairs. At least one row of the ground pins are depopulated. This allows for a complete layer of ground pins around each Tx pair and Rx pair, while still minimizing NEXT at resonant frequencies. In an embodiment with four rows of ground pins between Tx pairs and Rx pairs, up to two rows of ground pins can be depopulated.

Depopulating the ground pins minimizes the transfer of power between the Tx pairs and the Rx pairs. That is, by removing a resonating body from the path between the Tx pairs and the Rx pairs, a gap is formed that makes it more difficult to propagate energy. As can be appreciated, increasing to two depopulated rows can further decrease energy propagation between the Tx pairs and the Rx pairs.

In addition to pin depopulation, embodiments also include socket housing cutouts. In such an instance, rows of ground pins are removed, and the socket housing around the depopulated ground pins is also cut out. This removes additional material that participates in energy transfer (i.e., the socket housing) and replaces it with air. Air is much more resistant to energy propagation and NEXT is improved.

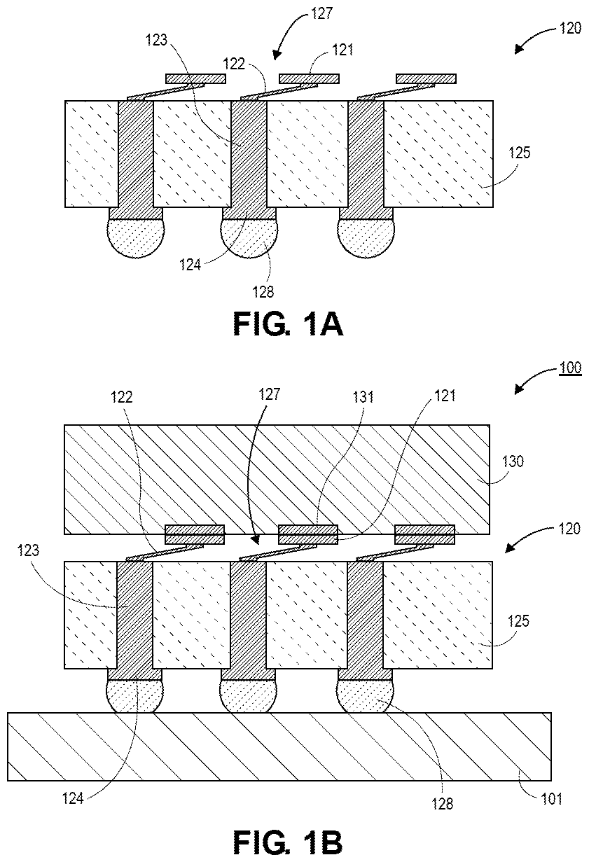

Referring now to FIG. 1A, a cross-sectional illustration of a socket module 120 is shown, in accordance with an embodiment. The socket module 120 may include a socket housing 125. The socket housing 125 may be an insulating or dielectric material. For example, the socket housing 125 may comprise a polymer or the like. In an embodiment the socket housing 125 may have any standard thickness. The socket housing 125 may have a thickness that is approximately 100 μm or greater, or approximately 1,000 μm or greater. As used herein, “approximately” may refer to a range of values that is within ten percent of the stated value. For example, approximately 100 μm may refer to a range between 90 μm and 110 μm.

In an embodiment, a plurality of pins 127 may be provided through the socket housing 125. The pins 127 may be any type of pin. In a particular embodiment, the pins 127 are LGA pins. In an embodiment, the pins 127 may be spaced in a regular pattern. For example, in FIG. 1A the pins 127 have a substantially uniform pitch. As will be described in greater detail below, the pins 127 may have a regular two-dimensional pattern. While three pins 127 are shown in FIG. 1A, it is to be appreciated that the socket module 120 may include any number of pins 127 (e.g., hundreds of pins 127, thousands of pins 127, etc.).

In an embodiment, the pins 127 may be suitable for various purposes. For example, some pins 127 may be signaling pins 127 (e.g., Tx pins 127 or Rx pins 127), some pins 127 may be ground pins 127, and some pins 127 may be power pins 127. In some instances, the pins 127 may look substantially similar to each other (e.g., same dimensions, same shape, etc.), even when used for different purposes.

In an embodiment, the pins 127 may include a first pad 121. The first pad 121 may be supported above a surface of the socket housing 125 by a cantilever interconnect 122. The opposite end of the cantilever interconnect 122 may be coupled to a via 123. The via 123 may pass through a thickness of the socket housing 125. A second pad 124 may be provided on the via 123 on a surface of the socket housing 125 opposite from the first pad 121. The first pad 121, the cantilever interconnect 122, the via 123, and the second pad 124 may comprise an electrically conductive material, such as copper or the like. In an embodiment, solder 128 or the like may be provided on the second pad 124.

Referring now to FIG. 1B, a cross-sectional illustration of an electronic system 100 is shown, in accordance with an embodiment. The electronic system 100 may include a board 101, such as a printed circuit board (PCB). The board 101 may be coupled to a package substrate 130 by the socket module 120. In an embodiment, the package substrate 130 may be an organic package substrate. The package substrate 130 may include a core, or the package substrate 130 may be coreless. Pads 131 on the package substrate 130 may be coupled to the pins 127. For example, pads 131 may interface with first pads 121 of the pins 127. The board 101 may be coupled to the socket module 120 by the solder 128.

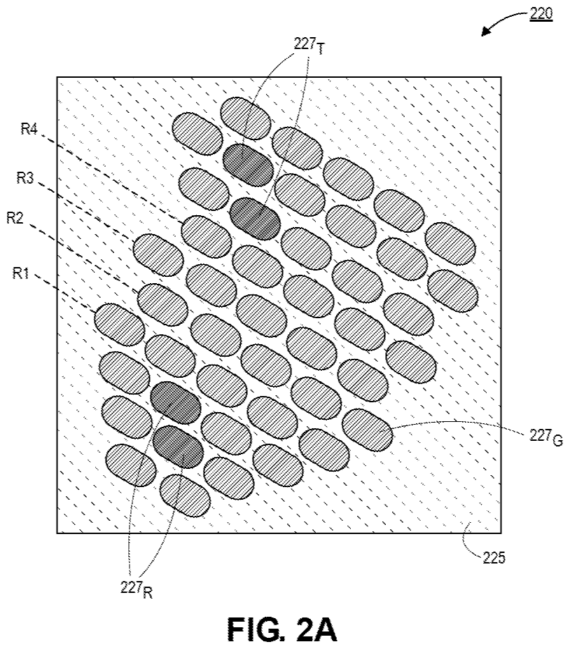

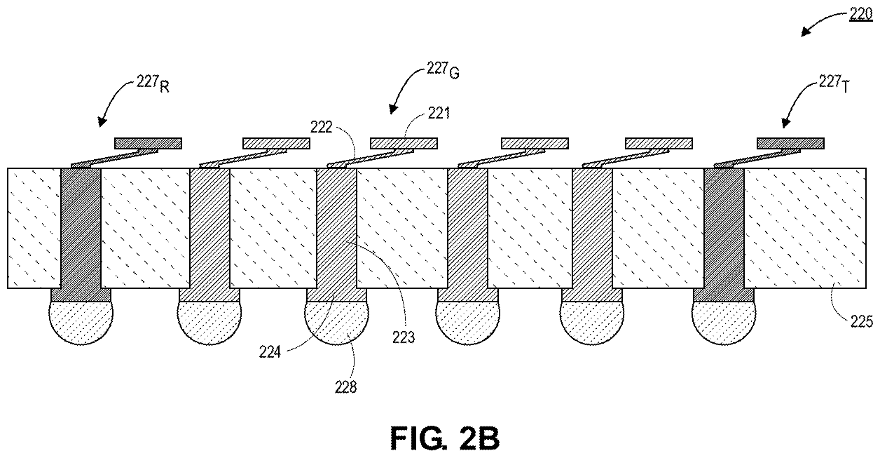

Referring now to FIG. 2A, a plan view illustration of a portion of a socket module 220 is shown, in accordance with an embodiment. The socket module 220 may include a socket housing 225. The socket housing 225 may be a polymer or the like. In an embodiment, an array of pins 227 are provided across the surface of the socket housing 225. In the illustrated embodiment, only the first pads (e.g., similar to first pads 121 above) are shown for simplicity. Cantilever structures, vias, and second pads are not visible in FIG. 2A.

In FIG. 2A the array of pins 227 includes a pattern. For example, rows of pins 227 are provided with each row being offset from neighboring rows. Such a pattern may sometimes be referred to as a hexagonal pattern. While a hexagonal pattern is shown in FIG. 2A, it is to be appreciated that any suitable pin 227 pattern may be used in accordance with embodiments disclosed herein. The pins 227 are shown as having pads with an oblong shape. Though, the pads may also be circular, square, rectangular, or any other suitable shape.

FIG. 2A illustrates various types of pins 227. Signaling pins 227 are provided in a first shading, and ground pins 227 are provided in a second shading. While shown with different shadings, it is to be appreciated that the structure of signaling pins 227 may be substantially similar to the structure of ground pins 227. In an embodiment, the signaling pins 227 may include Tx pins 227_{T} and Rx pins 227_{R}. The Tx pins 227_{T} may be grouped in a pair for differential signaling, and the Rx pins 227_{R} may be grouped in a pair for differential signaling.

Ground pins 227_{G} may surround the Tx pins 227_{T} and the Rx pins 227_{R}. The ground pins 227_{G} provide shielding that limits crosstalk until the resonance frequency is reached. In order to improve crosstalk reduction, three or more rows of ground pins 227_{G} may be provided between Tx pins 227_{T} and Rx pins 227_{R}. For example, rows R1, R2, R3, and R4 are provided between signaling pins 227.

Referring now to FIG. 2B, a cross-sectional illustration of a portion of the socket module 220 in FIG. 2A is shown, in accordance with an embodiment. As shown, the socket module 220 includes a socket housing 225. Pins 227 are provided through the socket housing 225. In an embodiment, the pins 227 may be LGA pins, though other pin architectures may also be used. The pins 227 may include a first pad 221 and a cantilever interconnect 222. The cantilever interconnect 222 couples the first pad 221 to a via 223 through the socket housing 225. A second pad 224 may be under the via 223, and a solder 228 may be provided on the second pad 224.

In an embodiment, the socket module 220 may include a Tx pin 227_{T} and an Rx pin 227_{R}. The Tx pin 227_{T} may be separated from the Rx pin 227_{R} by three or more ground pins 227_{G}. The ground pins 227_{G}, the Tx pin 227_{T}, and the Rx pin 227_{R} may all have a uniform pitch.

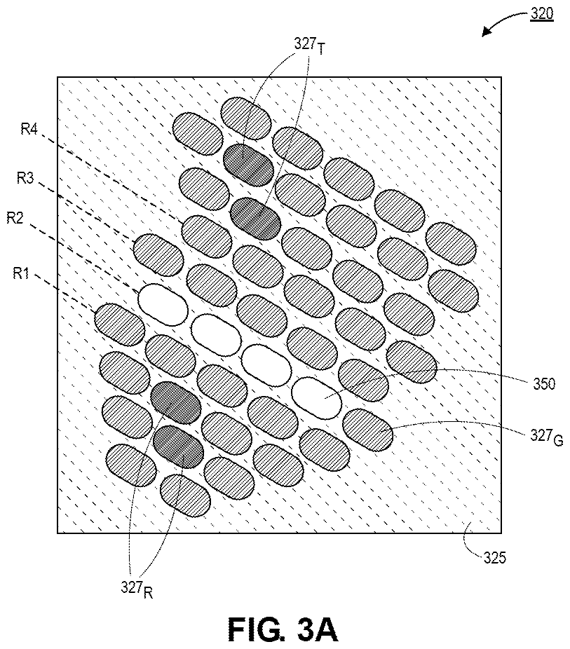

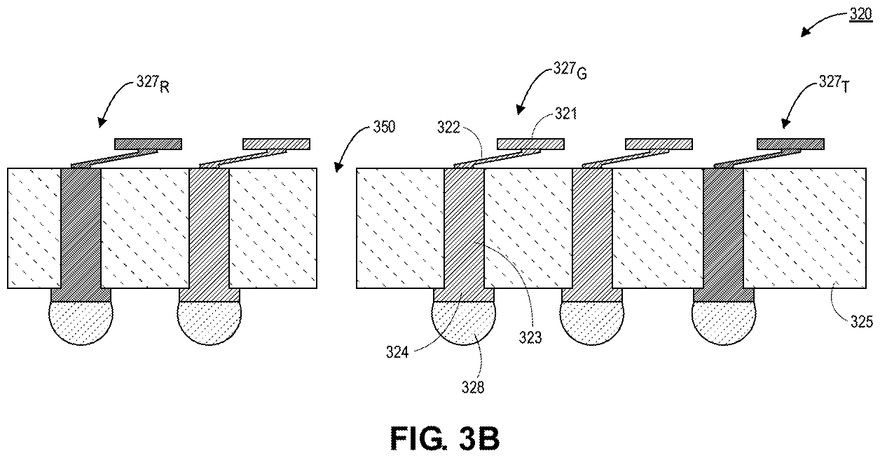

Referring now to FIG. 3A, a plan view illustration of a portion of a socket module 320 is shown, in accordance with an embodiment. The socket module 320 may include a socket housing 325. The socket housing 325 may be a polymer or the like. In an embodiment, an array of pins 327 are provided across the surface of the socket housing 325. In the illustrated embodiment, only the first pads (e.g., similar to first pads 121 above) are shown for simplicity. Cantilever structures, vias, and second pads are not visible in FIG. 3A.

In FIG. 3A the array of pins 327 includes a pattern. For example, rows of pins 327 are provided with each row being offset from neighboring rows in a hexagonal pattern. While a hexagonal pattern is shown in FIG. 3A, it is to be appreciated that any suitable pin 327 pattern may be used in accordance with embodiments disclosed herein. The pins 327 are shown as having pads with an oblong shape. Though, the pads may also be circular, square, rectangular, or any other suitable shape.

FIG. 3A illustrates various types of pins 327. Signaling pins 327 are provided in a first shading, and ground pins 327 are provided in a second shading. While shown with different shadings, it is to be appreciated that the structure of signaling pins 327 may be substantially similar to the structure of ground pins 327. In an embodiment, the signaling pins 327 may include Tx pins 327_{T} and Rx pins 327_{R}. The Tx pins 327_{T} may be grouped in a pair for differential signaling, and the Rx pins 327_{R} may be grouped in a pair for differential signaling.

Ground pins 327_{G} may surround the Tx pins 327_{T} and the Rx pins 327_{R}. The ground pins 327_{G} provide shielding that limits crosstalk until the resonance frequency is reached. In order to improve crosstalk reduction, three or more rows of ground pins 327_{G} may be provided between Tx pins 327_{T} and Rx pins 327_{R}. For example, rows R1, R2, R3, and R4 are provided between signaling pins 327.

In an embodiment, one or more ground pins 327_{G} between the Tx pins 327_{T} and the Rx pins 327_{R} are depopulated. For example, depopulated pins 350 are shown in FIG. 3A. As used herein, a “depopulated pin” is a void in the pattern of the array of pins 327. For example, where a pin 327 would otherwise be placed, a void is present. In some embodiments, a depopulated pin may omit the first pad, the cantilever interconnect, the via, and the second pad.

In the illustrated embodiment, the depopulated pins 350 include holes through the socket housing 325. The holes may have a diameter that is equal to the diameter of vias of existing pins 327. The holes may also be shaped similar to the first pads. For example, the holes in FIG. 3A are oblong. While holes are shown as one embodiment, it is to be appreciated that a depopulated pin 350 may also include an unmodified region of the socket housing 325.

The one or more depopulated pins 350 may be provided between the Tx pins 327_{T} and the Rx pins 327_{R}. For example, depopulated pins 350 are provided in a single row of the ground pins 327_{G}. More specifically, the depopulated pins 350 are provided along the second row R2. In other embodiments, the depopulated pins 350 may be provided in the third row R3. Providing the depopulated pins 350 in rows R2 or R3 still allows for the Tx pins 327_{T} and the Rx pins 327_{R} to be completely surrounded by ground pins 327_{G}.

Referring now to FIG. 3B, a cross-sectional illustration of a portion of the socket module 320 in FIG. 3A is shown, in accordance with an embodiment. As shown, the socket module 320 includes a socket housing 325. Pins 327 are provided through the socket housing 325. In an embodiment, the pins 327 may be LGA pins, though other pin architectures may also be used. The pins 327 may include a first pad 321 and a cantilever interconnect 322. The cantilever interconnect 322 couples the first pad 321 to a via 323 through the socket housing 325. A second pad 324 may be under the via 323, and a solder 328 may be provided on the second pad 324.

In an embodiment, the socket module 320 may include a Tx pin 327_{T} and an Rx pin 327_{R}. The Tx pin 327_{T} may be separated from the Rx pin 327_{R} by three or more ground pins 327_{G}. The ground pins 327_{G}, the Tx pin 327_{T}, and the Rx pin 327_{R} may all have a uniform pitch.

Further, one of the ground pins 327_{G} may be replaced with a depopulated pin 350. The depopulated pin 350 may include a hole that passes through a thickness of the socket housing 325. As shown, the width of the hole of the depopulated pin 350 may be substantially equal to a width of the vias 323. In an embodiment, the depopulated pin 350 may maintain the pitch between pins 327. That is, the hole of the depopulated pin 350 is a distance from a neighboring via 323 that is the same distance between two vias 323.

In some instances, the hole may be omitted, and the depopulated pin 350 may be an unaltered region of the socket housing 325. In such an embodiment, the pins 327 on opposite sides of the depopulated pin 350 may be spaced apart by twice the pitch without anything in between except for the socket housing 325.

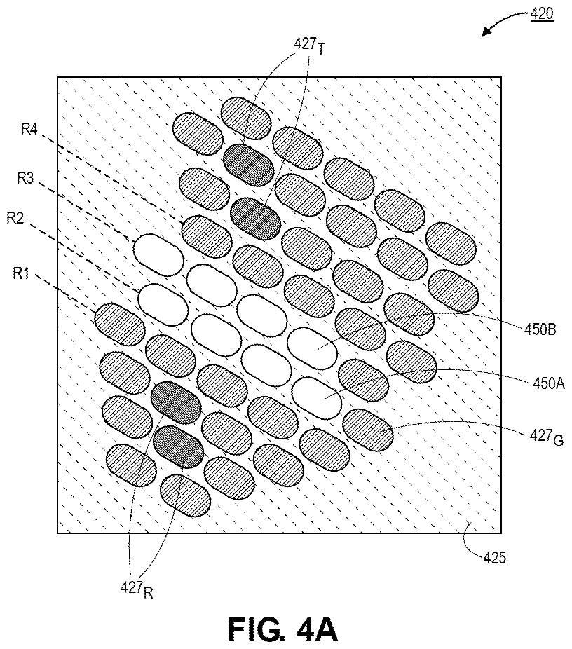

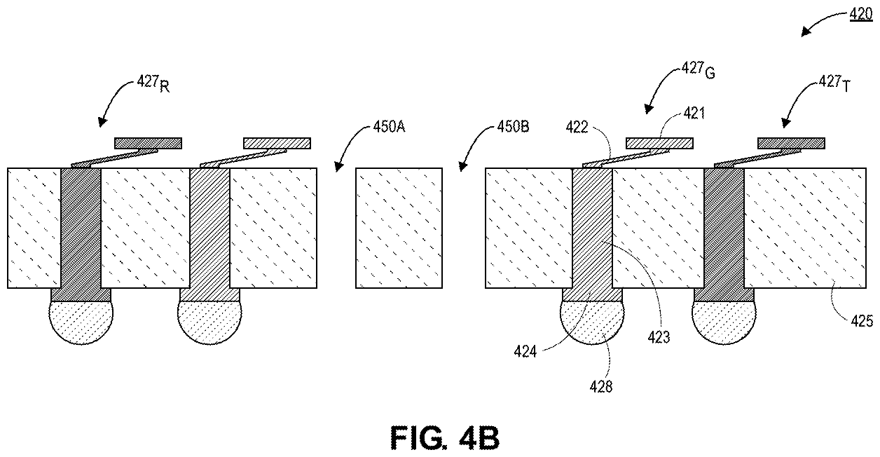

Referring now to FIG. 4A, a plan view illustration of a portion of a socket module 420 is shown, in accordance with an embodiment. The socket module 420 may include a socket housing 425. The socket housing 425 may be a polymer or the like. In an embodiment, an array of pins 427 are provided across the surface of the socket housing 425. In the illustrated embodiment, only the first pads (e.g., similar to first pads 121 above) are shown for simplicity. Cantilever structures, vias, and second pads are not visible in FIG. 4A.

In FIG. 4A the array of pins 427 includes a pattern. For example, rows of pins 427 are provided with each row being offset from neighboring rows in a hexagonal pattern. While a hexagonal pattern is shown in FIG. 4A, it is to be appreciated that any suitable pin 427 pattern may be used in accordance with embodiments disclosed herein. The pins 427 are shown as having pads with an oblong shape. Though, the pads may also be circular, square, rectangular, or any other suitable shape.

FIG. 4A illustrates various types of pins 427. Signaling pins 427 are provided in a first shading, and ground pins 427 are provided in a second shading. While shown with different shadings, it is to be appreciated that the structure of signaling pins 427 may be substantially similar to the structure of ground pins 427. In an embodiment, the signaling pins 427 may include Tx pins 427_{T} and Rx pins 427_{R}. The Tx pins 427_{T} may be grouped in a pair for differential signaling, and the Rx pins 427_{R} may be grouped in a pair for differential signaling.

Ground pins 427_{G} may surround the Tx pins 427_{T} and the Rx pins 427_{R}. The ground pins 427_{G} provide shielding that limits crosstalk until the resonance frequency is reached. In order to improve crosstalk reduction, three or more rows of ground pins 427_{G} may be provided between Tx pins 427_{T} and Rx pins 427_{R}. For example, rows R1, R2, R3, and R4 are provided between signaling pins 427.

In an embodiment, two or more ground pins 427_{G} between the Tx pins 427_{T} and the Rx pins 427_{R} are depopulated. For example, depopulated pins 450A and 450B are shown in FIG. 4A. In the illustrated embodiment, the depopulated pins 450A and 450B include holes through the socket housing 425. The holes may have a diameter that is equal to the diameter of vias of existing pins 427. The holes may also be shaped similar to the first pads. For example, the holes in FIG. 4A are oblong. While holes are shown as one embodiment, it is to be appreciated that a depopulated pin 450 may also include an unmodified region of the socket housing 425.

The two or more depopulated pins 450A and 450B may be provided between the Tx pins 427_{T} and the Rx pins 427_{R}. For example, depopulated pins 450A and 450B are provided in a pair of adjacent rows of ground pins 427_{G}. More specifically, the depopulated pins 450A and 450B are provided along the second row R2 and the third row R3. Providing the depopulated pins 450A and 450B in rows R2 and R3 still allows for the Tx pins 427_{T} and the Rx pins 427_{R} to be completely surrounded by ground pins 427_{G}.

Referring now to FIG. 4B, a cross-sectional illustration of a portion of the socket module 420 in FIG. 4A is shown, in accordance with an embodiment. As shown, the socket module 420 includes a socket housing 425. Pins 427 are provided through the socket housing 425. In an embodiment, the pins 427 may be LGA pins, though other pin architectures may also be used. The pins 427 may include a first pad 421 and a cantilever interconnect 422. The cantilever interconnect 422 couples the first pad 421 to a via 423 through the socket housing 425. A second pad 424 may be under the via 423, and a solder 428 may be provided on the second pad 424.

In an embodiment, the socket module 420 may include a Tx pin 427_{T} and an Rx pin 427_{R}. The Tx pin 427_{T} may be separated from the Rx pin 427_{R} by two or more ground pins 427_{G}. The ground pins 427_{G}, the Tx pin 427_{T}, and the Rx pin 427_{R} may all have a uniform pitch.

Further, two of the ground pins 427_{G} may be replaced with depopulated pins 450. The depopulated pins 450A and 450B may include holes that pass through a thickness of the socket housing 425. As shown, the width of the holes of the depopulated pins 450A and 450B may be substantially equal to a width of the vias 423. In an embodiment, the depopulated pins 450A and 450B may maintain the pitch between pins 427. That is, the hole of the depopulated pin 450 is a distance from a neighboring via 423 that is the same distance between two vias 423. The two holes may also be spaced at the pitch.

In some instances, the holes may be omitted, and the depopulated pins 450A and 450B may be an unaltered region of the socket housing 425. In such an embodiment, the pins 427 on opposite sides of the depopulated pins 450A and 450B may be spaced apart by three times the pitch without anything in between except for the socket housing 425.

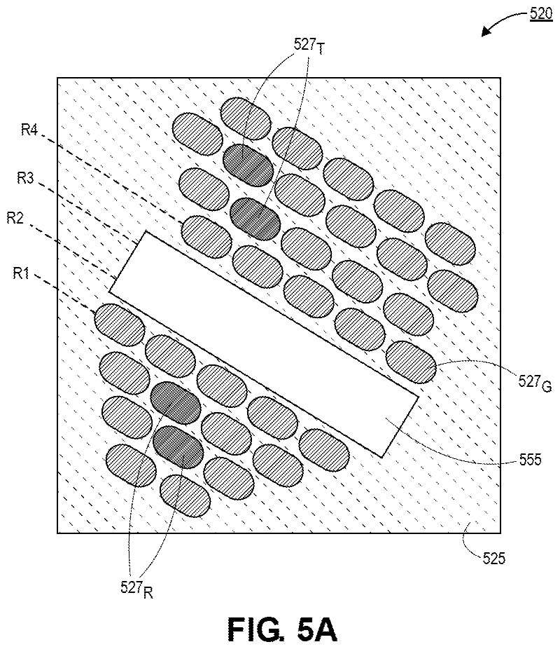

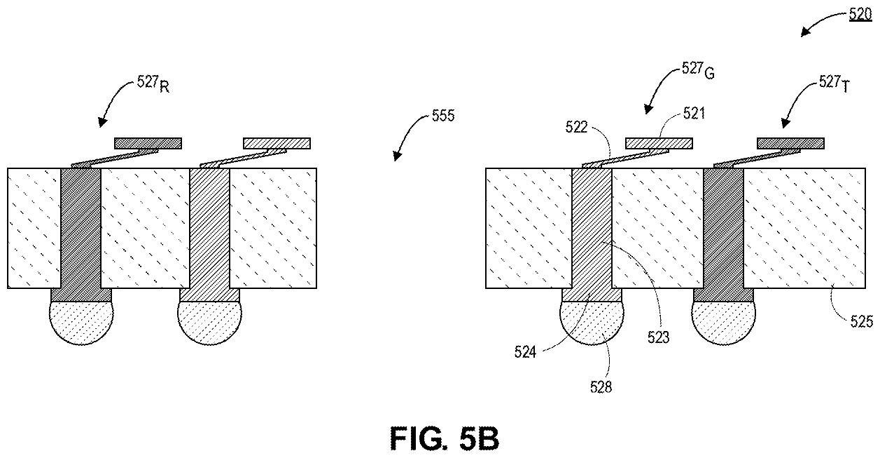

Referring now to FIG. 5A, a plan view illustration of a portion of a socket module 520 is shown, in accordance with an embodiment. The socket module 520 may include a socket housing 525. The socket housing 525 may be a polymer or the like. In an embodiment, an array of pins 527 are provided across the surface of the socket housing 525. In the illustrated embodiment, only the first pads (e.g., similar to first pads 121 above) are shown for simplicity. Cantilever structures, vias, and second pads are not visible in FIG. 5A.

In FIG. 5A the array of pins 527 includes a pattern. For example, rows of pins 527 are provided with each row being offset from neighboring rows in a hexagonal pattern. While a hexagonal pattern is shown in FIG. 5A, it is to be appreciated that any suitable pin 527 pattern may be used in accordance with embodiments disclosed herein. The pins 527 are shown as having pads with an oblong shape. Though, the pads may also be circular, square, rectangular, or any other suitable shape.

FIG. 5A illustrates various types of pins 527. Signaling pins 527 are provided in a first shading, and ground pins 527 are provided in a second shading. While shown with different shadings, it is to be appreciated that the structure of signaling pins 527 may be substantially similar to the structure of ground pins 527. In an embodiment, the signaling pins 527 may include Tx pins 527_{T} and Rx pins 527_{R}. The Tx pins 527_{T} may be grouped in a pair for differential signaling, and the Rx pins 527_{R} may be grouped in a pair for differential signaling.

Ground pins 527_{G} may surround the Tx pins 527_{T} and the Rx pins 527_{R}. The ground pins 527_{G} provide shielding that limits crosstalk until the resonance frequency is reached. In order to improve crosstalk reduction three or more rows of ground pins 527_{G} may be provided between Tx pins 527_{T} and Rx pins 527_{R}. For example, rows R1, R2, R3, and R4 are provided between signaling pins 527.

In an embodiment, a cutout 555 is provided between the Tx pins 527_{T} and the Rx pins 527_{R}. The cutout 555 may span one or more rows. For example, the cutout 555 in FIG. 5A extends into row R2 and row R3. The cutout 555 is provided in the place of a plurality of ground pins 527_{G}. The cutout 555 may be an opening that passes through an entire thickness of the socket housing 525. In other embodiments, the cutout 555 may be isolated to a single row.

Referring now to FIG. 5B, a cross-sectional illustration of a portion of the socket module 520 in FIG. 5A is shown, in accordance with an embodiment. As shown, the socket module 520 includes a socket housing 525. Pins 527 are provided through the socket housing 525. In an embodiment, the pins 527 may be LGA pins, though other pin architectures may also be used. The pins 527 may include a first pad 521 and a cantilever interconnect 522. The cantilever interconnect 522 couples the first pad 521 to a via 523 through the socket housing 525. A second pad 524 may be under the via 523, and a solder 528 may be provided on the second pad 524.

In an embodiment, the socket module 520 may include a Tx pin 527_{T} and an Rx pin 527_{R}. The Tx pin 527_{T} may be separated from the Rx pin 527_{R} by ground pins 527_{G}. The ground pins 527_{G}, the Tx pin 527_{T}, and the Rx pin 527_{R} may all have a uniform pitch.

Further, one or more ground pins 527_{G} may be replaced with a cutout 555. The cutout 555 may include a hole that pass through a thickness of the socket housing 525. The hole may have a width that is greater than a width of the vias 523. In some instances, the hole has a width that is at least twice as large as the width of the vias 523.

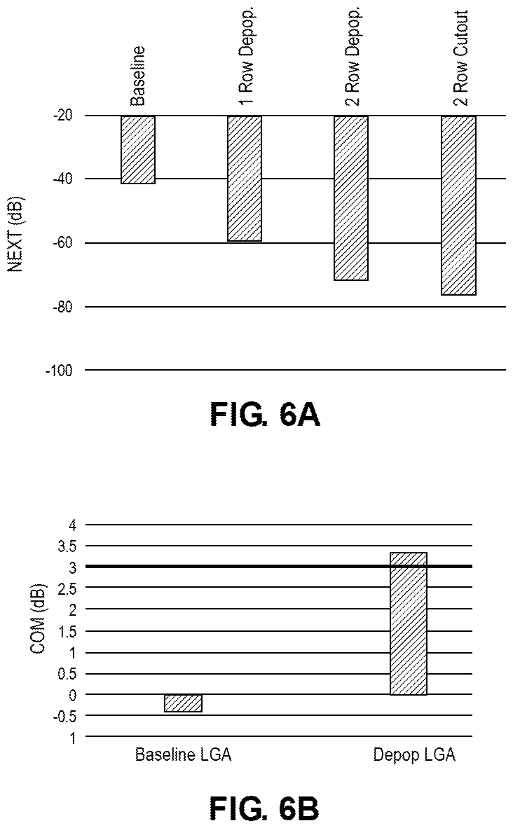

Referring now to FIG. 6A, a graph of the NEXT for various embodiments is shown, in accordance with an embodiment. The NEXT is measured at an operating frequency of 30 GHz. As shown, the baseline socket module (e.g., FIG. 2A) has the highest crosstalk. The 1 row depopulation socket module (e.g., FIG. 3A) has the next highest crosstalk, followed by the 2 row depopulation socket module (e.g., FIG. 4A). The cutout socket module (e.g., FIG. 5A) has the lowest NEXT value.

Referring now to FIG. 6B, a graph of the COM result for 112 Gbps data rates is shown, in accordance with an embodiment. As shown, the baseline LGA has a negative margin, showing no path for implementation of 112 Gbps. The bar on the right is a depopulated LGA in accordance with embodiments described herein. As shown, the target COM margin raises to above 3 dB, which is suitable for 112 Gbps operation. This shows NEXT reduction by a low-cost method with direct benefits towards enabling high speed data rates.

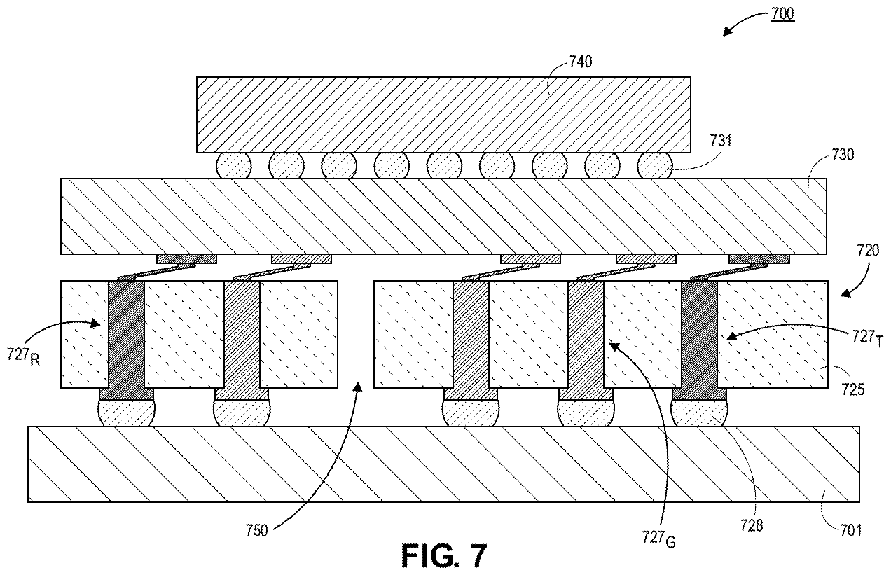

Referring now to FIG. 7, a cross-sectional illustration of an electronic system 700 is shown, in accordance with an embodiment. In an embodiment, the electronic system 700 may include a board 701, such as a PCB. The board 701 may be coupled to a package substrate 730 by a socket module 720. The socket module 720 may include a socket housing 725. Pins 727 may be provided through the socket housing 725. The pins 727 may include Tx pins 727_{T} and Rx pins 727_{R}. An array of ground pins 727_{G} may be provided between the Tx pin 727_{T} and the Rx pin 727_{R}. In an embodiment, one or more of the ground pins 727_{G} may be omitted and replaced with a depopulated pin 750. The depopulated pin 750 may include a hole, or the depopulated pin 750 may include an unaltered region of the socket housing 725. The socket module 720 may be coupled to the board 701 by solder 728 or the like.

In an embodiment, one or more dies 740 may be coupled to the package substrate 730 by interconnects 731. The interconnects 731 may be any suitable first level interconnect (FLI) architecture. The one or more dies 740 may be compute dies, such as a central processing unit (CPU), a graphics processing unit (GPU), an XPU, a system on a chip (SoC), a communications die, a memory, or the like.

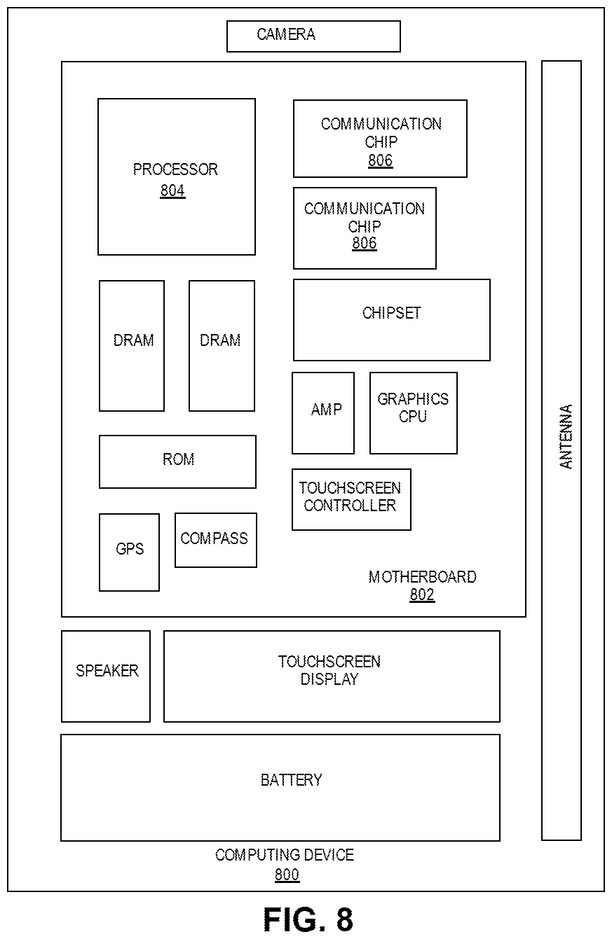

FIG. 8 illustrates a computing device 800 in accordance with one implementation of the disclosure. The computing device 800 houses a board 802. The board 802 may include a number of components, including but not limited to a processor 804 and at least one communication chip 806. The processor 804 is physically and electrically coupled to the board 802. In some implementations the at least one communication chip 806 is also physically and electrically coupled to the board 802. In further implementations, the communication chip 806 is part of the processor 804.

These other components include, but are not limited to, volatile memory (e.g., DRAM), non-volatile memory (e.g., ROM), flash memory, a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth).

The communication chip 806 enables wireless communications for the transfer of data to and from the computing device 800. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 806 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device 800 may include a plurality of communication chips 806. For instance, a first communication chip 806 may be dedicated to shorter range wireless communications such as Wi-Fi and Bluetooth and a second communication chip 806 may be dedicated to longer range wireless communications such as GPS, EDGE, GPRS, CDMA, WiMAX, LTE, Ev-DO, and others.

The processor 804 of the computing device 800 includes an integrated circuit die packaged within the processor 804. In some implementations of the disclosure, the integrated circuit die of the processor may be part of an electronic package that includes a socket module with one or more depopulated ground pins in rows between signaling pins, in accordance with embodiments described herein. The term “processor” may refer to any device or portion of a device that processes electronic data from registers and/or memory to transform that electronic data into other electronic data that may be stored in registers and/or memory.

The communication chip 806 also includes an integrated circuit die packaged within the communication chip 806. In accordance with another implementation of the disclosure, the integrated circuit die of the communication chip may be part of an electronic package that includes a socket module with one or more depopulated ground pins in rows between signaling pins, in accordance with embodiments described herein.

In an embodiment, the computing device 800 may be part of any apparatus. For example, the computing device may be part of a personal computer, a server, a mobile device, a tablet, an automobile, or the like. That is, the computing device 800 is not limited to being used for any particular type of system, and the computing device 800 may be included in any apparatus that may benefit from computing functionality.

The above description of illustrated implementations of the disclosure, including what is described in the Abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize.

These modifications may be made to the disclosure in light of the above detailed description. The terms used in the following claims should not be construed to limit the disclosure to the specific implementations disclosed in the specification and the claims. Rather, the scope of the disclosure is to be determined entirely by the following claims, which are to be construed in accordance with established doctrines of claim interpretation.

Example 1: a socket module, comprising: a housing; a first pin through the housing in a first row of pins; a second pin through the housing in a second row of pins; and at least three intervening rows of pins between the first row of pins and the second row of pins, wherein one or more pin locations in the at least three intervening rows of pins are depopulated.

Example 2: the socket module of Example 1, wherein a first intervening row of pins adjacent to the first row of pins is fully populated, and wherein a second intervening row of pins adjacent to the second row of pins is fully populated.

Example 3: the socket module of Example 1 or Example 2, wherein each depopulated pin includes a hole through the housing.

Example 4: the socket module of Example 3, wherein at least two depopulated pins are adjacent to each other, and wherein the holes are coupled together to form a cutout.

Example 5: the socket module of Examples 1-4, wherein four intervening rows of pins are provided between the first row of pins and the second row of pins.

Example 6: the socket module of Example 5, wherein depopulated pins are provided in at least two of the intervening rows of pins.

Example 7: the socket module of Examples 1-6, wherein the first pin and the second pin are configured to propagate signals.

Example 8: the socket module of Examples 1-7, wherein pins in the intervening rows of pins are configured to be ground pins.

Example 9: the socket module of Examples 1-8, wherein the housing is a polymer.

Example 10: the socket module of Examples 1-9, wherein the socket module is coupled to a board.

Example 11: a socket module, comprising: a housing; an array of pins that pass through the housing, wherein the array of pins are arranged in a pattern; and a plurality of holes through the housing, wherein the holes are integrated into the pattern.

Example 12: the socket module of Example 11, wherein two or more adjacent holes are coupled together to form a cutout through the housing.

Example 13: the socket module of Example 11 or Example 12, wherein the pattern includes a plurality of rows.

Example 14: the socket module of Example 13, wherein a first hole is in a first row, and wherein a second hole is in a second row, wherein the first hole is adjacent to the second hole.

Example 15: the socket module of Examples 11-14, wherein the pins are land grid array (LGA) pins.

Example 16: the socket module of Examples 11-15, wherein the array of pins include a Tx pair of pins and an Rx pair of pins, wherein three or more intervening rows of pins are between the Tx pair of pins and the Rx pair of pins, and wherein at least one of the holes is within at least one of the three or more intervening rows of pins.

Example 17: the socket module of Example 16, wherein at least one of the holes is within at least two of the three or more intervening rows of pins.

Example 18: an electronic system, comprising: a board; a package substrate coupled to the board by a socket module, wherein the socket module comprises: a housing; an array of pins through the housing; and one or more holes through the housing, wherein at least one hole is provided between a pair of pins; and a die coupled to the package substrate.

Example 19: the electronic system of Example 18, wherein the one or more holes are provided between a Tx pair of pins and an Rx pair of pins.

Example 20: the electronic system of Example 18 or Example 19, wherein the electronic system is part of a personal computer, a server, a mobile device, a tablet, or an automobile.

What is claimed is:

1. A socket module, comprising:
a housing;
a first pin through the housing in a first row of pins;
a second pin through the housing in a second row of pins; and
at least three intervening rows of pins between the first row of pins and the second row of pins, wherein one or more pin locations in the at least three intervening rows of pins are depopulated.

2. The socket module of claim 1, wherein a first intervening row of pins adjacent to the first row of pins is fully populated, and wherein a second intervening row of pins adjacent to the second row of pins is fully populated.

3. The socket module of claim 1, wherein each depopulated pin includes a hole through the housing.

4. The socket module of claim 3, wherein at least two depopulated pins are adjacent to each other, and wherein the holes are coupled together to form a cutout.

5. The socket module of claim 1, wherein four intervening rows of pins are provided between the first row of pins and the second row of pins.

6. The socket module of claim 5, wherein depopulated pins are provided in at least two of the intervening rows of pins.

7. The socket module of claim 1, wherein the first pin and the second pin are configured to propagate signals.

8. The socket module of claim 1, wherein pins in the intervening rows of pins are configured to be ground pins.

9. The socket module of claim 1, wherein the housing is a polymer.

10. The socket module of claim 1, wherein the socket module is coupled to a board.

11. A socket module, comprising:
a housing;
an array of pins that pass through the housing, wherein the array of pins are arranged in a pattern; and
a plurality of holes through the housing, wherein the holes are integrated into the pattern.

12. The socket module of claim 11, wherein two or more adjacent holes are coupled together to form a cutout through the housing.

13. The socket module of claim 11, wherein the pattern includes a plurality of rows.

14. The socket module of claim 13, wherein a first hole is in a first row, and wherein a second hole is in a second row, wherein the first hole is adjacent to the second hole.

15. The socket module of claim 11, wherein the pins are land grid array (LGA) pins.

16. The socket module of claim 11, wherein the array of pins include a Tx pair of pins and an Rx pair of pins, wherein three or more intervening rows of pins are between the Tx pair of pins and the Rx pair of pins, and wherein at least one of the holes is within at least one of the three or more intervening rows of pins.

17. The socket module of claim 16, wherein at least one of the holes is within at least two of the three or more intervening rows of pins.

18. An electronic system, comprising:
a board;
a package substrate coupled to the board by a socket module, wherein the socket module comprises:
a housing;
an array of pins through the housing; and
one or more holes through the housing, wherein at least one hole is provided between a pair of pins; and
a die coupled to the package substrate.

19. The electronic system of claim 18, wherein the one or more holes are provided between a Tx pair of pins and an Rx pair of pins.

20. The electronic system of claim 18, wherein the electronic system is part of a personal computer, a server, a mobile device, a tablet, or an automobile.
